(19) United States
(12) Patent Application Publication
(10) Pub. No.: US 2023/0377997 A1
(43) Pub. Date: Nov. 23, 2023

(54) CONTACT FORMATION PROCESS FOR CMOS DEVICES

(71) Applicant: Applied Materials, Inc., Santa Clara, CA (US)

(72) Inventors: Nicolas Louis BREIL, San Jose, CA (US); Balasubramanian PRANATHARTHIHARAN, Santa Clara, CA (US); Benjamin COLOMBEAU, Salem, MA (US); Anchuan WANG, San Jose, CA (US)

(21) Appl. No.: 18/123,783

(22) Filed: Mar. 20, 2023

Related U.S. Application Data
(60) Provisional application No. 63/332,622, filed on Apr. 19, 2022.

(51) Int. Cl. H01L 21/8238; H01L 21/02; H01L 21/768

(52) U.S. Cl. CPC H01L 21/823871; H01L 21/02063; H01L 21/76843; H01L 21/76895

(57) ABSTRACT

A method of forming a contact layer in a semiconductor structure includes performing a pre-clean process on exposed surfaces of a plurality of first semiconductor regions and a plurality of second semiconductor regions formed on a substrate, wherein the exposed surfaces of the plurality of first and second semiconductor regions are each disposed within openings formed in a dielectric layer disposed over the substrate, performing a first selective epitaxial deposition process to form a first contact layer on the exposed surfaces of the first semiconductor regions and a second contact layer on the exposed surface of the second semiconductor regions, performing a patterning process to form a patterned stack, wherein the patterned stack comprises a patterned layer that comprises openings formed over the first contact layer disposed within each opening in the dielectric layer and a portion of the patterned layer that is disposed over each second contact layer disposed within each opening in the dielectric layer, and performing a selective removal process to remove the first contact layer selectively to the plurality of first semiconductor regions, the dielectric layer, and the patterned layer.

### CROSS-REFERENCE TO RELATED APPLICATIONS

This application claims priority to U.S. Provisional Application Ser. No. 63/332,622 filed Apr. 19, 2022, which is herein incorporated by reference in its entirety.

### BACKGROUND

### Field

Embodiments described herein generally relate to semiconductor device fabrication, and more particularly, to systems and methods of forming a contact within a semiconductor structure.

### Description of the Related Art

Multi-gate metal-oxide-semiconductor field-effect transistors (MOSFETs), such as complementary metal-oxide semiconductor (CMOS) devices, pose challenges in manufacturability due to their three-dimensional (3D) designs and small sizes. In advanced CMOS devices, an epitaxial layer of silicon-containing material (e.g., boron-doped p-type silicon germanium or phosphorus-doped n-type silicon) formed at a bottom of a trench contact is often utilized to lower a contact resistivity into the 10⁻⁹ Ω·cm² regime, and achieve the required performance for advanced CMOS technologies.

However, the formation and patterning of such epitaxial layer, for example, using a hard mask to protect an n-MOS region or a p-MOS region, may damage various portions of the CMOS device, such as spacers, gate cap layers, or epitaxially grown layers.

Therefore, there is a need for methods and systems that can form a contact that includes an epitaxial layer of silicon-containing material at a selected portion of a semiconductor device.

### SUMMARY

Embodiments of the present disclosure provide a method of forming a contact layer in a semiconductor structure. The method includes performing a pre-clean process on exposed surfaces of a plurality of first semiconductor regions and a plurality of second semiconductor regions formed on a substrate, wherein the exposed surfaces of the plurality of first and second semiconductor regions are each disposed within openings formed in a dielectric layer disposed over the substrate, performing a first selective epitaxial deposition process to form a first contact layer on the exposed surfaces of the first semiconductor regions and a second contact layer on the exposed surface of the second semiconductor regions, performing a patterning process to form a patterned stack, wherein the patterned stack comprises a patterned layer that comprises openings formed over the first contact layer disposed within each opening in the dielectric layer and a portion of the patterned layer that is disposed over each second contact layer disposed within each opening in the dielectric layer, and performing a selective removal process to remove the first contact layer selectively to the plurality of first semiconductor regions, the dielectric layer, and the patterned layer.

Embodiments of the present disclosure provide a method of forming a contact layer in a semiconductor structure. The method includes performing a pre-clean process on exposed surfaces of a plurality of first semiconductor regions and a plurality of second semiconductor regions formed on a substrate, wherein the exposed surfaces of the plurality of first and second semiconductor regions are each disposed within openings formed in a dielectric layer disposed over the substrate, performing a first selective epitaxial deposition process to simultaneously form a first contact layer having a first thickness on the exposed surface of the first semiconductor regions and a second contact layer having a second thickness on the exposed surface of the second semiconductor regions, wherein the second thickness is larger than the first thickness, and performing a selective removal process to remove the first contact layer and the second contact layer selectively to the plurality of first semiconductor regions, and the dielectric layer until the first contact layer is substantially removed from the first semiconductor regions and a portion of the second contact layer remains on the second semiconductor regions.

Embodiments of the present disclosure provide a processing system, including a first processing chamber, a second processing chamber, a third processing chamber, and a system controller configured to perform, in the first processing chamber, a pre-clean process on exposed surfaces of a plurality of first semiconductor regions and a plurality of second semiconductor regions formed on a substrate, perform, in the second processing chamber, a first selective deposition process to epitaxially form a first contact layer on the exposed surfaces of the first semiconductor regions and a second contact layer on the exposed surface of the second semiconductor regions of the substrate, and perform, in the third processing chamber, a selective removal process to remove the first contact layer selectively to the first semiconductor regions.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top view of a multi-chamber processing system according to one or more embodiments of the present disclosure.

FIG. 2A is a cross sectional view of a processing chamber, according to one or more embodiments.

FIG. 2B is an enlarged view of a portion of the processing chamber of FIG. 2A.

FIG. 3 is a cross sectional view of a processing chamber, according to one or more embodiments.

FIG. 4 is a cross sectional view of a processing chamber, according to one or more embodiments.

FIG. 5 depicts a process flow diagram of a method of forming a contact layer in a semiconductor structure according to a first embodiment of the present disclosure.

FIGS. 6A, 6B, 6C, 6D, 6E, 6F, and 6G are cross-sectional views of a portion of a semiconductor structure corresponding to various states of the method of FIG. 5.

FIG. 7 depicts a process flow diagram of a method of forming a contact layer in a semiconductor structure according to a second embodiment of the present disclosure.

FIGS. 8A, 8B, 8C, 8D, and 8E are cross-sectional views of a portion of the semiconductor structure corresponding to various states of the method of FIG. 7.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The embodiments described herein provide methods and systems for forming a contact that includes an epitaxial layer of silicon-containing material (e.g., boron-doped p-type silicon germanium or phosphorus-doped n-type silicon) at a selected portion (e.g., on an exposed surface of a layer of silicon or silicon germanium) of a structure that is used to form a CMOS device. The methods and systems may be particularly useful for forming, in a semiconductor structure having a region that includes silicon, a region that includes silicon germanium, and a dielectric layer formed thereover, an epitaxial layer that includes silicon germanium selectively on an exposed surface of the silicon germanium material within an opening or feature (e.g., contact trench) formed in the dielectric layer. Unlike conventional processes that require the formation of a hard mask and various etching and patterning process steps, which tend to damage the fabricated semiconductor structures (e.g., spacers, gate cap, etc.), to form a contact, the processes described herein are configured to form a contact without damaging these previously formed semiconductor structures.

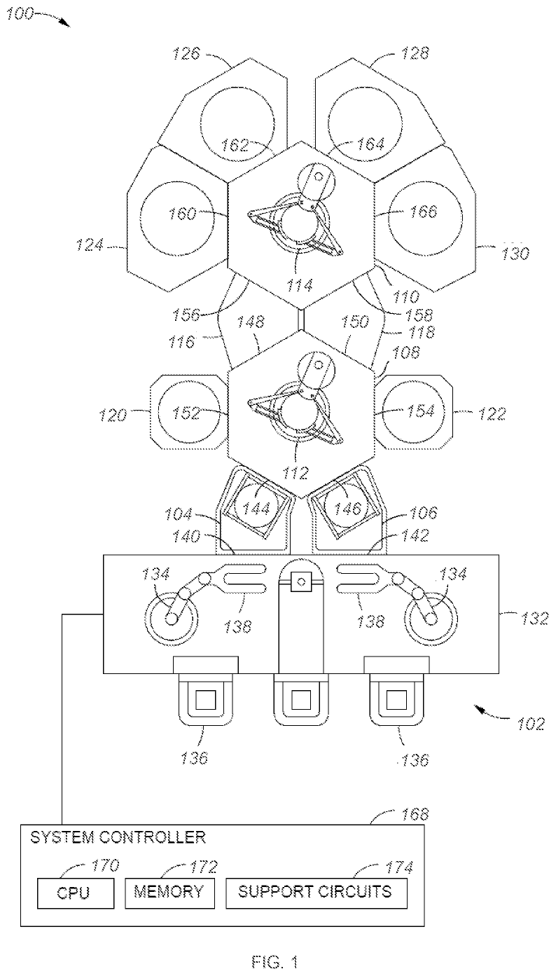

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, the processing chamber 124 can be capable of performing a selective removal process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Centura™ Epi chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

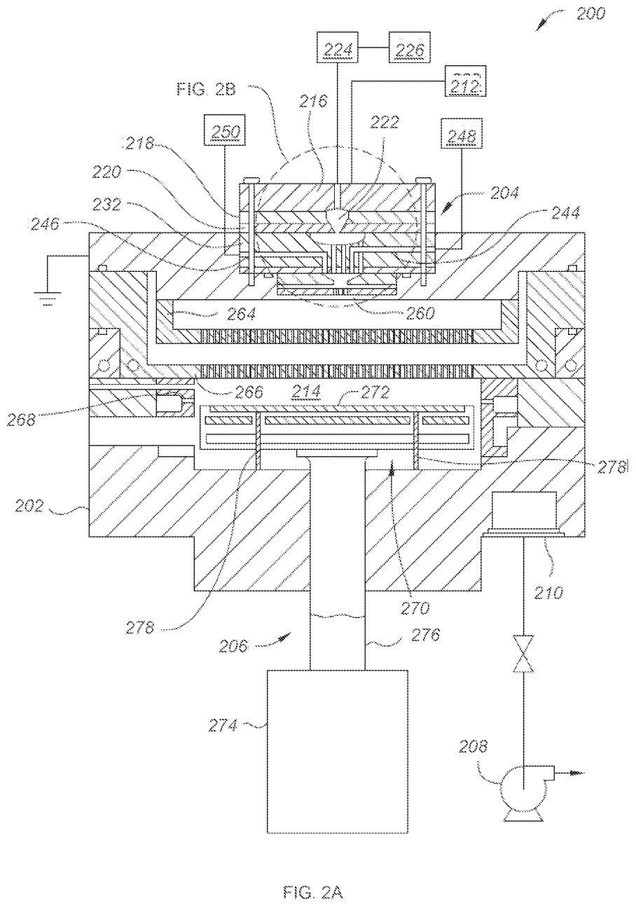

FIG. 2A is a cross sectional view of a processing chamber 200, according to one or more embodiments, that is adapted to perform a pre-clean process as detailed below. The processing chamber 200 may be the processing chamber 122 shown in FIG. 1. FIG. 2B is an enlarged view of a portion of the processing chamber 200 of FIG. 2A.

The processing chamber 200 may be particularly useful for performing a thermal or plasma-based cleaning process and/or a plasma assisted dry etch process. The processing chamber 200 includes a chamber body 202, a lid assembly 204, and a support assembly 206. The lid assembly 204 is disposed at an upper end of the chamber body 202, and the support assembly 206 is at least partially disposed within the chamber body 202. A vacuum system can be used to remove gases from processing chamber 200. The vacuum system includes a vacuum pump 208 coupled to a vacuum port 210 disposed in the chamber body 202. The processing chamber 200 also includes a controller 212 for controlling processes within the processing chamber 200.

The lid assembly 204 includes stacked components adapted to provide precursor gases and/or a plasma to a processing region 214 within the processing chamber 200. A first plate 216 is coupled to a second plate 218. A third plate 220 is coupled to the second plate 218. The lid assembly 204 may be connected to a power source (not shown) for supplying a plasma to a cone-shaped chamber 222 formed in the lid assembly 204. The lid assembly 204 can also be connected to a remote plasma source 224 that creates the plasma upstream of the lid stack. The remote plasma cavity (e.g., the processing region 214, the first plate 216, and the second plate 218 in FIGS. 2A-2B) is coupled to a gas source 226 (or the gas source 226 is coupled directly to the lid assembly 204 in the absence of the remote plasma source 224). The gas source 226 may include a gas source that is adapted to provide helium, argon, or other inert gas. In some configurations, the gas provided by the gas source 226 can be energized into a plasma that is provided to the lid assembly 204 by use of the remote plasma source 224. In alternate embodiments, the gas source 226 may provide process gases that can be activated by the remote plasma source 224 prior to being introduced to a surface of the substrate that is disposed within the processing chamber 200. Referring to FIG. 2B, the cone-shaped chamber 222 has an opening 228 that allows a formed plasma to flow from the remote plasma source 224 to a volume 230 formed in a fourth plate 232 of the lid assembly 204.

In some configurations of the lid assembly 204, a plasma is generated within the cone-shaped chamber 222 by the application of energy delivered from a plasma source. In one example, the energy can be provided by biasing the lid assembly 204 to capacitively couple RF, VHF and/or UHF energy to the gases positioned in the cone-shaped chamber 222. In this configuration of the lid assembly 204, the remote plasma source 224 may not be used, or not be installed within the lid assembly 204.

A central conduit 234, which is formed in the fourth plate 232, is adapted to provide the plasma generated species provided from the volume 230 through a fifth plate 236 to a mixing chamber 238 formed in a sixth plate 240 of the lid assembly 204. The central conduit 234 communicates with the mixing chamber 238 through an opening 242 in the fifth plate 236. The opening 242 may have a diameter less than, greater than or the same as a diameter of the central conduit 234. In the embodiment of FIG. 2B, the opening 242 has diameter the same as the central conduit 234.

The fourth plate 232 also includes inlets 244 and 246 that are adapted to provide gases to the mixing chamber 238. The inlet 244 is coupled to a first gas source 248 and the inlet 246 is coupled to a second gas source 250. The first gas source 248 and the second gas source 250 may include processing gases as well as inert gases, for example inert gases such as argon and/or helium, utilized as a carrier gas. The first gas source 248 may include ammonia (NH₃) as well as argon (Ar). The second gas source 250 may contain fluorine containing gases, hydrogen containing gases, or a combination thereof. In one example, the second gas source 250 may contain hydrogen fluoride (HF) as well as argon (Ar).

As illustrated in FIG. 2B, in some configurations, the inlet 244 is coupled to the mixing chamber 238 through a cylindrical channel 252 (shown in phantom) and holes 254 formed in the fifth plate 236. The inlet 246 is coupled to the mixing chamber 238 through a cylindrical channel 256 (shown in phantom) and holes 258 formed in the fifth plate 236. The holes 254, 258 formed in the fifth plate 236 are generally sized so that they enable a uniform flow of gases, which are provided from their respective gas source 248, 250, into the mixing chamber 238. In one configuration, the holes 258 have a diameter that is less than a width of the opening defined by the opposing sidewalls of the cylindrical channel 256 formed in the fourth plate 232. The holes 258 are typically distributed around the circumference of the center-line of the cylindrical channel 256 to provide uniform fluid flow into the mixing chamber 238. In one configuration, the holes 254 have a diameter that is less than a width of the opening defined by the opposing sidewalls of the cylindrical channel 252 formed the fourth plate 232. The holes 254 are typically distributed around the circumference of the center-line of the cylindrical channel 252 to provide uniform fluid flow into the mixing chamber 238.

The inlets 244 and 246 provide respective fluid flow paths laterally through the fourth plate 232, turning toward and penetrating through the fifth plate 236 to the mixing chamber 238. The lid assembly 204 also includes a seventh plate or first gas distributor 260, which may be a gas distribution plate, such as a showerhead, where the various gases mixed in the lid assembly 204 are flowed through perforations 262 formed therein. The perforations 262 are in fluid communication with the mixing chamber 238 to provide flow pathways from the mixing chamber 238 through the first gas distributor 260. Referring back to FIG. 2A, a blocker plate 264 and a gas distribution plate, such as a second gas distributor 266, which may be a gas distribution plate, such as a showerhead, is disposed below the lid assembly 204.

Alternatively, a different cleaning process may be utilized to clean the substrate surface. For example, a remote plasma containing helium (He) and ammonia (NH₃) may be introduced into the processing chamber 200 through the lid assembly 204, while ammonia (NH₃) may be directly injected into the processing chamber 200 via a separate gas inlet 268 that is disposed at a side of the chamber body 202 and coupled to a gas source (not shown).

The support assembly 206 may include a substrate support 270 to support a substrate 272 thereon during processing. The substrate support 270 may be coupled to an actuator 274 by a shaft 276 which extends through a centrally-located opening formed in a bottom of the chamber body 202. The actuator 274 may be flexibly sealed to the chamber body 202 by bellows (not shown) that prevent vacuum leakage around the shaft 276. The actuator 274 allows the substrate support 270 to be moved vertically within the chamber body 202 between a processing position and a loading position. The loading position is slightly below the opening of a tunnel (not shown) formed in a sidewall of the chamber body 202.

The substrate support 270 has a flat, or a substantially flat, substrate supporting surface for supporting a substrate 272 to be processed thereon. The substrate support 270 may be moved vertically within the chamber body 202 by the actuator 274, which is coupled to the substrate support 270 by the shaft 276. For some steps, the substrate support 270 may be elevated to a position in close proximity to the lid assembly 204 to control the temperature of the substrate 272 being processed. As such, the substrate 272 may be heated via radiation emitted from the second gas distributor 266, or another radiant source, or by convection or conduction from the second gas distributor 266 through an intervening gas. In some process steps, the substrate may be disposed on lift pins 278 to perform additional thermal processing steps, such as performing an annealing step.

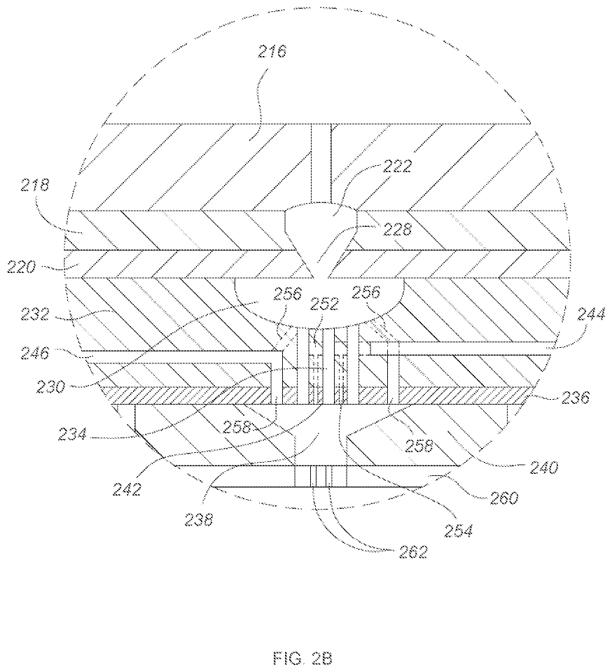

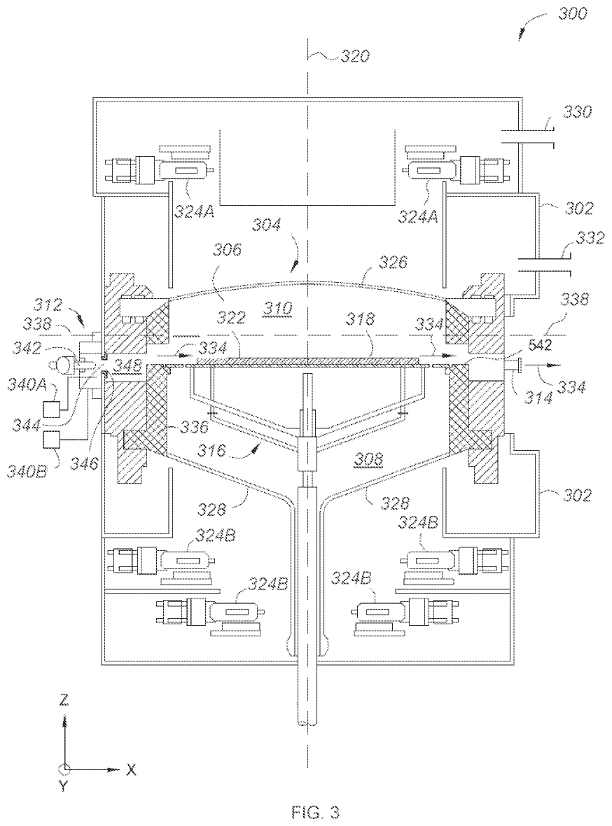

FIG. 3 is a cross sectional view of a processing chamber 300, according to one or more embodiments, that is adapted to perform an epitaxial (Epi) deposition process as detailed below. The processing chamber 300 may be the processing chamber 126, 128, or 130 shown in FIG. 1.

The processing chamber 300 includes a housing structure 302 made of a process resistant material, such as aluminum or stainless steel, for example 316L stainless steel. The housing structure 302 encloses various functioning elements of the processing chamber 300, such as a quartz chamber 304, which includes an upper quartz chamber 306, and a lower quartz chamber 308, in which a processing volume 310 is contained. Reactive species are provided to the quartz chamber 304 by a gas distribution assembly 312, and processing byproducts are removed from the processing volume 310 by an outlet port 314, which is typically in communication with a vacuum source (not shown).

A substrate support 316 is adapted to receive a substrate 318 that is transferred to the processing volume 310. The substrate support 316 is disposed along a longitudinal axis 320 of the processing chamber 300. The substrate support 316 may be made of a ceramic material or a graphite material coated with a silicon material, such as silicon carbide, or other process resistant material. Reactive species from precursor reactant materials are applied to a surface 322 of the substrate 318, and byproducts may be subsequently removed from the surface 322 of the substrate 318. Heating of the substrate 318 and/or the processing volume 310 may be provided by radiation sources, such as upper lamp modules 324A and lower lamp modules 324B.

In one embodiment, the upper lamp modules 324A and the lower lamp modules 324B are infrared (IR) lamps. Non-thermal energy or radiation from the lamp modules 324A and 324B travels through an upper quartz window 326 of the upper quartz chamber 306, and through a lower quartz window 328 of the lower quartz chamber 308. Cooling gases for the upper quartz chamber 306, if needed, enter through an inlet 330 and exit through an outlet 332. Precursor reactant materials, as well as diluent, purge and vent gases for the processing chamber 300, enter through the gas distribution assembly 312 and exit through the outlet port 314. While the upper quartz window 326 is shown as being curved or convex, the upper quartz window 326 may be planar or concave as the pressure on both sides of the upper quartz window 326 is substantially the same (i.e., atmospheric pressure).

The low wavelength radiation in the processing volume 310, which is used to energize reactive species and assist in adsorption of reactants and desorption of process byproducts from the surface 322 of the substrate 318, typically ranges from about 0.8 μm to about 1.2 μm, for example, between about 0.95 μm to about 1.05 μm, with combinations of various wavelengths being provided, depending, for example, on the composition of the film which is being epitaxially grown.

The component gases enter the processing volume 310 via the gas distribution assembly 312. Gas flows from the gas distribution assembly 312 and exits through the outlet port 314 as shown generally by a flow path 334. Combinations of component gases, which are used to clean/passivate a substrate surface, or to form the silicon and/or germanium-containing film that is being epitaxially grown, are typically mixed prior to entry into the processing volume 310. The overall pressure in the processing volume 310 may be adjusted by a valve (not shown) on the outlet port 314. At least a portion of the interior surface of the processing volume 310 is covered by a liner 336. In one embodiment, the liner 336 comprises a quartz material that is opaque. In this manner, the chamber wall is insulated from the heat in the processing volume 310.

The temperature of surfaces in the processing volume 310 may be controlled within a temperature range of about 200° C. to about 600° C., or greater, by the flow of a cooling gas, which enters through the inlet 330 and exits through the outlet 332, in combination with radiation from the upper lamp modules 324A positioned above the upper quartz window 326. The temperature in the lower quartz chamber 308 may be controlled within a temperature range of about 200° C. to about 600° C. or greater, by adjusting the speed of a blower unit which is not shown, and by radiation from the lower lamp modules 324B disposed below the lower quartz chamber 308. The pressure in the processing volume 310 may be between about 0.1 Torr to about 600 Torr, such as between about 5 Torr to about 30 Torr.

The temperature on the surface 322 of the substrate 318 may be controlled by power adjustment to the lower lamp modules 324B in the lower quartz chamber 308, or by power adjustment to both the upper lamp modules 324A overlying the upper quartz window 326, and the lower lamp modules 324B in the lower quartz chamber 308. The power density in the processing volume 310 may be between about 40 W/cm² to about 400 W/cm², such as about 80 W/cm² to about 120 W/cm².

In one aspect, the gas distribution assembly 312 is disposed normal to, or in a radial direction 338 relative to, the longitudinal axis 320 of the processing chamber 300 or the substrate 318. In this orientation, the gas distribution assembly 312 is adapted to flow process gases in the radial direction 338 across, or parallel to, the surface 322 of the substrate 318. In one processing application, the process gases are preheated at the point of introduction to the processing chamber 300 to initiate preheating of the gases prior to introduction to the processing volume 310, and/or to break specific bonds in the gases. In this manner, surface reaction kinetics may be modified independently from the thermal temperature of the substrate 318.

In operation, precursors used to form silicon (Si) and silicon germanium (SiGe) blanket or selective epitaxial films are provided to the gas distribution assembly 312 from the one or more gas sources 340A and 340B. IR lamps 342 (only one is shown in FIG. 3) may be utilized to heat the precursors within the gas distribution assembly 312 as well as along the flow path 334. The gas sources 340A, 340B may be coupled the gas distribution assembly 312 in a manner adapted to facilitate introduction zones within the gas distribution assembly 312, such as a radial outer zone and a radial inner zone between the outer zones when viewed in from a top plan view. The gas sources 340A, 340B may include valves (not shown) to control the rate of introduction into the zones.

The gas sources 340A, 340B may include silicon precursors such as silanes, including silane (SiH₄), disilane (Si₂H₆), dichlorosilane (SiH₂Cl₂), hexachlorodisilane (Si₂Cl₆), dibromosilane (SiH₂Br₂), higher order silanes, derivatives thereof, and combinations thereof. The gas sources 340A, 340B may also include germanium containing precursors, such as germane (GeH₄), digermane (Ge₂H₆), germanium tetrachloride (GeCl₄), dichlorogermane (GeH₂Cl₂), derivatives thereof, and combinations thereof. The silicon and/or germanium containing precursors may be used in combination with hydrogen chloride (HCl), chlorine gas (Cl₂), hydrogen bromide (HBr), and combinations thereof. The gas sources 340A, 340B may include one or more of the silicon and germanium containing precursors in one or both of the gas sources 340A, 340B.

The precursor materials enter the processing volume 310 through openings or holes 344 (only one is shown in FIG. 3) in the perforated plate 346 in this excited state, which in one embodiment is a quartz material, having the holes 344 formed therethrough. The perforated plate 346 is transparent to IR energy, and may be made of a clear quartz material. In other embodiments, the perforated plate 346 may be any material that is transparent to IR energy and is resistant to process chemistry and other processing chemistries. The energized precursor materials flow toward the processing volume 310 through the holes 344 in the perforated plate 346, and through channels 348 (only one is shown in FIG. 3). A portion of the photons and non-thermal energy from the IR lamps 342 also passes through the holes 344, the perforated plate 346, and channels 348 facilitated by a reflective material and/or surface disposed on the interior surfaces of the gas distribution assembly 312, thereby illuminating the flow path 334 of the precursor materials. In this manner, the vibrational energy of the precursor materials may be maintained from the point of introduction to the processing volume 310 along the flow path.

FIG. 4 is a cross sectional view of a processing chamber 400, according to one or more embodiments, that is adapted to perform a selective removal process (SRP) as detailed below. The processing chamber 400 may be the processing chamber 124 shown in FIG. 1.

The processing chamber 400 includes a chamber body 402, a lid assembly 404, and a support assembly 406. The lid assembly 404 is disposed at an upper end of the chamber body 402, and the support assembly 406 is at least partially disposed within the chamber body 402. A vacuum system can be used to remove gases from processing chamber 400. The vacuum system includes a vacuum pump 408 coupled to a vacuum port 410 disposed in the chamber body 402.

The lid assembly 404 includes a remote plasma system (RPS) 412 that may process a fluorine-containing precursor which then travels through a gas inlet assembly 414. Two distinct gas supply channels are visible within the gas inlet assembly 414. A first channel 416 carries a gas that passes through the RPS 412, while a second channel 418 bypasses the RPS 412. Either channel may be used for the fluorine-containing precursor. In some implementations, the first channel 416 may be used for a process gas and the second channel 418 may be used for a treatment gas. A lid (also referred to as a “conductive top portion”) 420 and a perforated partition (also referred to as a “showerhead”) 422 are shown with an insulating ring 424 in between, which allows an AC potential to be applied to the lid 420 relative to the perforated partition 422. The AC potential strikes a plasma in a chamber plasma region 426. The process gas may travel through the first channel 416 into the chamber plasma region 426 and may be excited by a plasma in the chamber plasma region 426 alone or in combination with the RPS 412. If the process gas (e.g., the fluorine-containing precursor) flows through the second channel 418, then only the chamber plasma region 426 is used for excitation. The perforated partition 422 separates the chamber plasma region 426 from a substrate processing region 428 beneath the perforated partition 422. The perforated partition 422 allows a plasma present in the chamber plasma region 426 to avoid directly exciting gases in the substrate processing region 428, while still allowing excited species to travel from the chamber plasma region 426 into the substrate processing region 428.

The perforated partition 422 is positioned between the chamber plasma region 426 and the substrate processing region 428 and allows plasma effluents (excited derivatives of precursors or other gases) created within the RPS 412 and/or the chamber plasma region 426 to pass through through-holes 430 that traverse the thickness of the plate. The perforated partition 422 also has one or more hollow volumes 432 which can be filled with a precursor in the form of a vapor or gas (such as a fluorine-containing precursor) and pass through small holes 434 into the substrate processing region 428 but not directly into the chamber plasma region 426. The perforated partition 422 is thicker than the length of the smallest diameter 436 of the through-holes 430 in this embodiment. The length 438 of the smallest diameter 436 of the through-holes 430 may be restricted by forming larger diameter portions of the through-holes 430 part way through the perforated partition 422 to maintain a significant concentration of excited species penetrating from the chamber plasma region 426 to the substrate processing region 428. The length of the smallest diameter 436 of the through-holes 430 may be the same order of magnitude as the smallest diameter 436 of the through-holes 430 or less in some embodiments.

The perforated partition 422 may be adapted to serve the purpose of an ion suppressor. Alternatively, a separate processing chamber element may be included (not shown) which suppresses the ion concentration traveling into the substrate processing region 428. The lid 420 and the perforated partition 422 may function as a first electrode and a second electrode, respectively, so that the lid 420 and the perforated partition 422 may receive different electric voltages. In these configurations, electrical power (e.g., RF power) may be applied to the lid 420, the perforated partition 422, or both. For example, electrical power may be applied to the lid 420 while the perforated partition 422 (serving as ion suppressor) is grounded. An RF generator may provide electrical power to the lid 420 and/or the perforated partition 422. The voltage applied to the lid 420 may facilitate a uniform distribution of plasma (i.e., reduce localized plasma) within the chamber plasma region 426. To enable the formation of a plasma in the chamber plasma region 426, the insulating ring 424 may electrically insulate the lid 420 from the perforated partition 422. The insulating ring 424 may be made from a ceramic and may have a high breakdown voltage to avoid sparking. Portions of the processing chamber 400 near the capacitively-coupled plasma components that are described above may further include a cooling unit (not shown) that includes one or more cooling fluid channels to cool surfaces exposed to the plasma with a circulating coolant (e.g., water).

In the embodiment shown, the perforated partition 422 may distribute (via the through-holes 430) process gases which contain fluorine, hydrogen and/or plasma effluents of such process gases upon excitation by a plasma in the chamber plasma region 426. In some embodiments, the process gas introduced into the RPS 412 and/or the chamber plasma region 426 may contain fluorine (e.g., F₂, NF₃ or XeF₂). The process gas may also include a diluent gases such as helium (He), argon (Ar), or nitrogen (N₂). Plasma effluents may include ionized or neutral derivatives of the process gas and may also be referred to herein as radical-fluorine and/or radical-hydrogen referring to the atomic constituent of the process gas introduced.

The through-holes 430 suppress the migration of ionically-charged species out of the chamber plasma region 426 while allowing uncharged neutral or radical species to pass through the perforated partition 422 into the substrate processing region 428. These uncharged species may include highly reactive species that are transported with less-reactive carrier gas by the through-holes 430. As noted above, the migration of ionic species by the through-holes 430 may be reduced, and in some instances completely suppressed. Controlling the amount of ionic species passing through the perforated partition 422 provides increased control over the gas mixture brought into contact with the underlying patterned substrate, which in turn increases control of the deposition and/or etch characteristics of the gas mixture. For example, adjustments in the ion concentration of the gas mixture can alter the etch selectivity (e.g., a ratio of the etch rate of silicon germanium to the etch rate of silicon).

In some embodiments, the number of the through-holes 430 may be between about 60 and about 2000. The through-holes 430 may have a variety of shapes but are most easily made round. The smallest diameter 436 of the through-holes 430 may be between about 0.5 mm and about 20 mm or between about 1 mm and about 6 mm in some embodiments. There is also latitude in choosing the cross-sectional shape of through-holes, which may be made conical, cylindrical or combinations of the two shapes. The number of the small holes 434 used to introduce unexcited precursors into the substrate processing region 428 may be between about 100 and about 5000 or between about 500 and about 2000 in different embodiments. The diameter of the small holes 434 may be between about 0.1 mm and about 2 mm.

The through-holes 430 may control the passage of the plasma-activated gas (i.e., the ionic, radical, and/or neutral species) through the perforated partition 422. For example, the aspect ratio of the holes (i.e., the hole diameter to length) and/or the geometry of the holes may be controlled so that the flow of ionically-charged species in the activated gas passing through the perforated partition 422 is reduced. The through-holes 430 in the perforated partition 422 may include a tapered portion that faces the chamber plasma region 426, and a cylindrical portion that faces the substrate processing region 428. The cylindrical portion may be proportioned and dimensioned to control the flow of ionic species passing into the substrate processing region 428. An adjustable electrical bias may also be applied to the perforated partition 422 as an additional means to control the flow of ionic species through the perforated partition 422.

Alternatively, through-holes 430 may have a smaller inner diameter (ID) toward the top surface of the perforated partition 422 and a larger ID toward the bottom surface. In addition, the bottom edge of the through-holes 430 may be chamfered to help evenly distribute the plasma effluents in the substrate processing region 428 as the plasma effluents exit the perforated partition 422 and promote even distribution of the plasma effluents and precursor gases. The smaller ID may be placed at a variety of locations along the through-holes 430 and still allow the perforated partition 422 to reduce the ion density within substrate processing region 428. The reduction in ion density results from an increase in the number of collisions with walls prior to entry into the substrate processing region 428. Each collision increases the probability that an ion is neutralized by the acquisition or loss of an electron from the wall. Generally speaking, the smaller ID of the through-holes 430 may be between about 0.2 mm and about 20 mm. In other embodiments, the smaller ID may be between about 1 mm and 6 mm or between about 0.2 mm and about 5 mm. Further, aspect ratios of the through-holes 430 (i.e., the smaller ID to hole length) may be approximately 1 to 20. The smaller ID of the through-holes 430 may be the minimum ID found along the length of the through-holes 430. The cross sectional shape of through-holes 430 may be generally cylindrical, conical, or any combination thereof.

The support assembly 406 may include a substrate support 440 to support a substrate 442 thereon during processing. The substrate support 440 may be coupled to an actuator 444 by a shaft 446 which extends through a centrally-located opening formed in a bottom of the chamber body 402. The actuator 444 may be flexibly sealed to the chamber body 402 by bellows (not shown) that prevent vacuum leakage around the shaft 446. The actuator 444 allows the substrate support 440 to be moved vertically within the chamber body 402 between a processing position and a loading position. The loading position is slightly below the opening of a tunnel (not shown) formed in a sidewall of the chamber body 402.

The substrate support 440 has a flat, or a substantially flat, substrate supporting surface for supporting a substrate 442 to be processed thereon. The substrate support 440 may be moved vertically within the chamber body 402 by the actuator 444, which is coupled to the substrate support 440 by the shaft 446. In some process steps, the substrate may be disposed on lift pins 488 to perform additional thermal processing steps, such as performing an annealing step.

### Process Examples

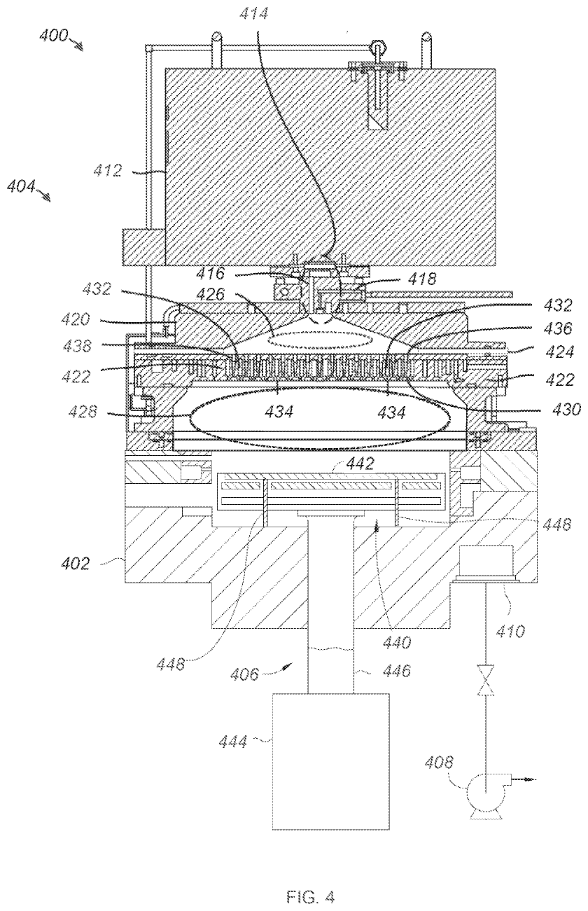

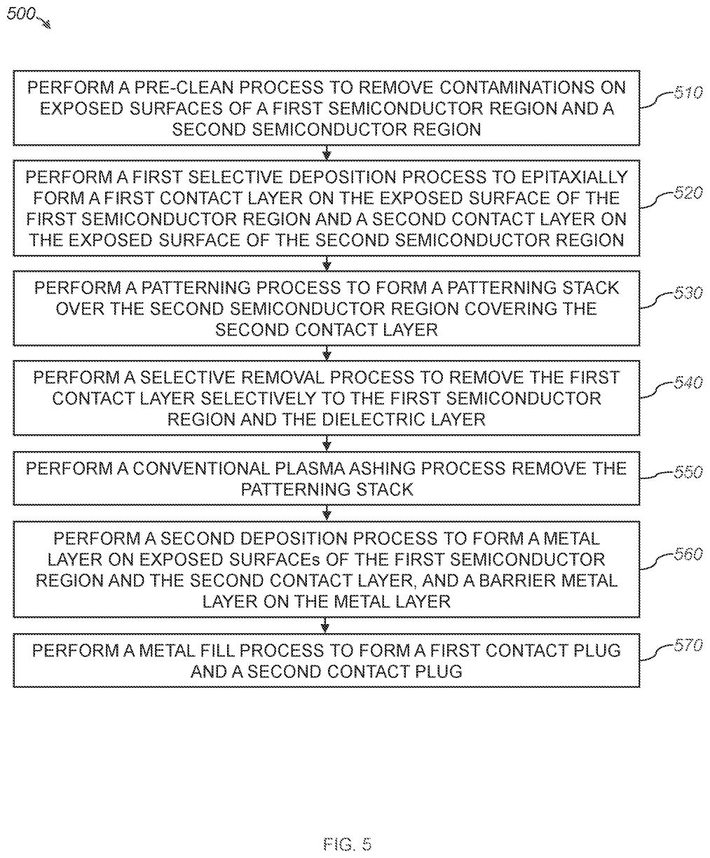

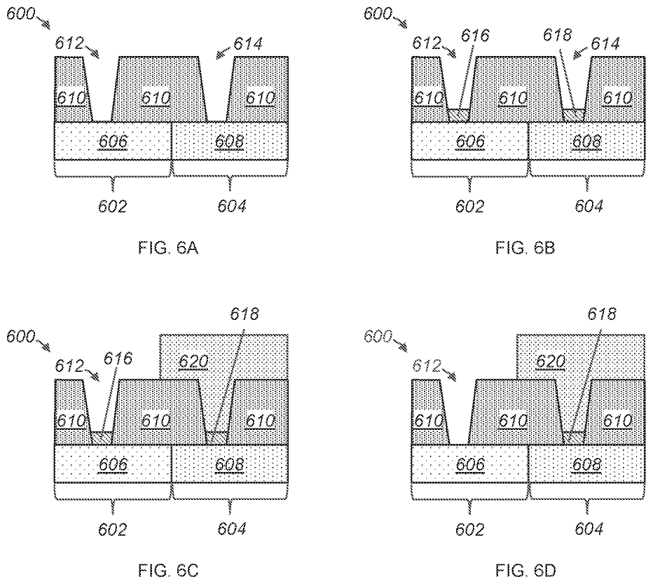

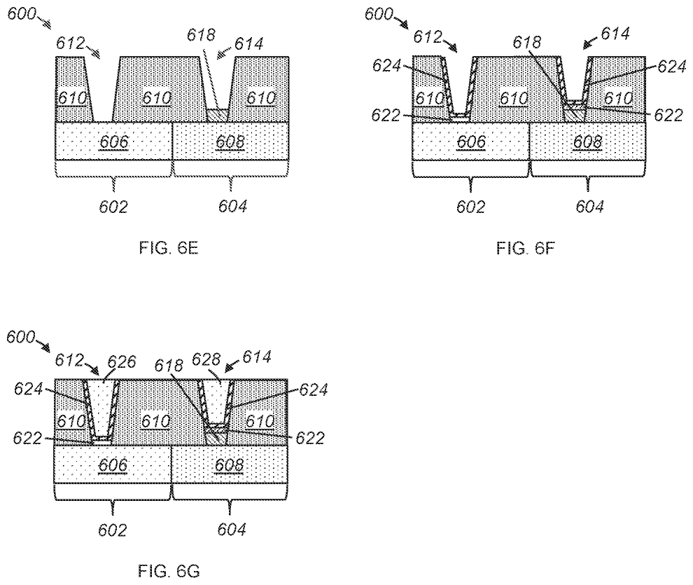

FIG. 5 depicts a process flow diagram of a method 500 of forming a contact layer in a semiconductor structure 600 according to a first embodiment of the present disclosure. FIGS. 6A, 6B, 6C, 6D, 6E, 6F, and 6G are cross-sectional views of a portion of the semiconductor structure 600 corresponding to various states of the method 500. It should be understood that FIGS. 6A, 6B, 6C, 6D, 6E, 6F, and 6G illustrate only partial schematic views of the semiconductor structure 600, and the semiconductor structure 600 may contain any number of transistor sections and additional materials having aspects as illustrated in the figures. It should also be noted that although the method illustrated in FIG. 5 is described sequentially, other process sequences that include one or more operations that have been omitted and/or added, and/or has been rearranged in another desirable order, fall within the scope of the embodiments of the disclosure provided herein.

Referring to FIGS. 6A, 6B, 6C, 6D, 6E, 6F, and 6G, the semiconductor structure 600 may include a first transistor device 602 and a second transistor device 604 formed on a substrate.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

As shown in FIG. 6A, a portion of a first transistor device 602 of a plurality of first transistor devices formed on the substrate includes a first semiconductor region 606 formed of a first material. A portion of a second transistor device 604 of a plurality of second transistor devices formed on the substrate includes a second semiconductor region 608 formed of a second material. The first and second materials include materials having differing compositions, such that the second material can be selectively etched relative to the first material (i.e., an etch rate of the second material is higher than an etch rate of the first material). The etch selectivity of the second material (i.e., a ratio of the etch rate of the second material to the etch rate of the first material) is between about 10:1 to 500:1. Example combinations of the first material and the second material include silicon (Si)/silicon germanium (SiGe), germanium (Ge)/silicon germanium (SiGe), or silicon (Si)/germanium tin (GeSn), respectively.

The first semiconductor regions 606 may be doped with n-type dopants such as phosphorus (P), antimony (Sb), with the concentration between about 10²⁰ cm⁻³ and 5·x 10²¹ cm⁻³, depending upon the desired conductive characteristic of the first transistor device 602. The second semiconductor regions 608 may be doped with p-type dopants such as boron (B) or gallium (Ga), with the concentration of between about 10²⁰ cm⁻³ and 5·x 10²¹ cm⁻³, depending upon the desired conductive characteristic of the second transistor device 604.

The semiconductor structure 600 further includes a dielectric layer 610 having a first opening 612 formed over each of the first semiconductor regions 606 and a second opening 614 formed over each of the second semiconductor regions 608. The dielectric layer 610 may be formed of a dielectric material, such as silicon dioxide (SiO₂) or silicon nitride (Si₃N₄).

The first semiconductor regions 606 and the second semiconductor regions 608 may be formed using any suitable deposition technique, such as epitaxial (Epi) deposition, chemical vapor deposition (CVD), atomic layer deposition (ALD), or physical vapor deposition (PVD), and the openings 612 and 614 are formed by a patterning technique, such as a lithography and etch process.

The method 500 begins with a pre-clean process in block 510. The pre-clean process may be performed in a processing chamber, such as the processing chamber 122 shown in FIG. 1, or the processing chamber 200 shown in FIG. 2.

The pre-clean process is configured to remove contaminants, such as native oxide layers, or patterning residues (e.g., fluorocarbons) formed on the exposed surfaces of the first semiconductor regions 606 within the first openings 612 and the second semiconductor regions 608 within the second openings 614. The pre-clean process is used to prepare the exposed surfaces of the first semiconductor regions 606 within the first openings 612 and the second semiconductor regions 608 within the second openings 614 on which an epitaxial layer can be formed in a subsequent epitaxial deposition process. The pre-clean process can be used to further modulate a growth rate of a subsequently deposited epitaxial layer on surfaces of the first semiconductor regions 606 (e.g. silicon (Si)) and surfaces of the second semiconductor regions 608 (e.g., silicon germanium (SiGe) in the subsequent epitaxial deposition process. The modulation of the growth rate of a subsequently deposited epitaxial layer can be performed by controlling amount of residual materials disposed at the surfaces of the first semiconductor regions 606 and the second semiconductor regions 608, such as the amount of remaining oxide material, surface activation process, and/or altering the crystal structure (e.g., promoting an amorphous or crystalline structure) of the material at the surfaces of the first semiconductor regions 606 and the second semiconductor regions 608 after performing the pre-clean process. In some embodiments, the pre-clean process can have some etch rate selectivity between a surface of a SiGe:B containing region that is oxidized and a surface of a Si:P containing region that is oxidized, such that the pre-clean process will “clean” SiGe:B surface (e.g., remove the oxides formed thereon) and leave the Si:P surface with at least a portion of an oxide layer formed thereon, for example.

The pre-clean process may include an anisotropic remote plasma assisted dry etch process, such as a reactive ion etching (RIE) process, using a plasma formed from a gas including argon (Ar), helium (He), or a combination thereof. The plasma effluents directionally bombard and remove a remaining dielectric layer within the first opening 612 and the second opening 614.

The pre-clean process may include an isotropic plasma etching process, such as a SiCoNi™ dry chemical etching process, using a plasma formed from a gas including ammonia (NH₃), nitrogen trifluoride (NF₃), hydrogen fluoride (HF), or a combination thereof, and a carrier gas, such as nitrogen (N₂), hydrogen (H₂), or a combination thereof. The dry chemical etching process is selective for oxide layers, and thus does not readily etch silicon, germanium, or nitride layers regardless of whether the layers are amorphous, crystalline or polycrystalline. Selectivity of the dry chemical etching process for oxide versus silicon or germanium is at least about 3:1, and usually 5:1 or better, sometimes 10:1. The dry chemical etching process is also highly selective of oxide versus nitride. The selectivity of the dry chemical etching process versus nitride is at least about 3:1, usually 5:1 or better, sometimes 10:1.

The pre-clean process may include an inductively coupled plasma (ICP) etching process, using a plasma formed from a gas including chlorine (Cl₂) and hydrogen (H₂), and a carrier gas including argon (Ar) and helium (He). The ICP etching process is used to form deep ridges with smooth sidewalls in silicon.

The pre-clean process may include a surface activation process based on the isotropic plasma etching process, such as a SiCoNi™ dry chemical etching process, using a plasma formed from a gas including ammonia (NH₃), nitrogen trifluoride (NF₃), hydrogen fluoride (HF), or a combination thereof, and a carrier gas, such as nitrogen (N₂), hydrogen (H₂), or a combination thereof. In one example, the plasma cleaning process is a remote plasma assisted dry cleaning process which involves the concurrent exposure of a substrate to HF and NH₃, and optionally including plasma by-products of one or more of the gases. Inert gases such as argon and helium may also be used. Any one, or combination of the three gases, inert/HF/NH₃ may be exposed to energy, as described above, to form a plasma thereof that is used to remove the desired contaminants and passivate at least portions of the surface of the substrate. Any residual compounds remaining on the surface of the substrate after exposing the substrate to the plasma can then be removed by subsequently heating the substrate to a desired temperature.

In block 520, a first selective deposition process is performed to epitaxially form a first contact layer 616 on an exposed surface of the first semiconductor region 606 within the first opening 612, and a second contact layer 618 on an exposed surface of the second semiconductor region 608 within the second opening 614, as shown in FIG. 6B. The first selective deposition process may be performed in a processing chamber, such as the processing chamber 126, 128, or 130 shown in FIG. 1, or the processing chamber 300 shown in FIG. 3.

The first contact layer 616 is subsequently removed, as discussed below. The second contact layer 618 is formed as interfaces between the second semiconductor regions 608 and a metal contact plug to be formed within the second opening 614, to minimize parasitic resistance. The first contact layer 616 and the second contact layer 618 are formed of a third material. Examples of the third material includes silicon germanium (SiGe) with a ratio of germanium (Ge) ranging between 20% and 100%. The first contact layer 616 and the second contact layer 618 may be doped with p-type dopants such as boron (B) or gallium (Ga), with the concentration of between about 10²⁰ cm⁻³ and 5 x·10²¹ cm⁻³, depending upon the desired conductive characteristic of the second contact layer 618.

In some embodiments, the first selective deposition process includes a first deposition process and a first etch process. The first deposition process is an epitaxial deposition process. The selectivity in the first selective deposition process may arise from differences in nucleation of the third material on the exposed surfaces of the first semiconductor regions 606 and the second semiconductor regions 608 (e.g., silicon (Si) or silicon germanium (SiGe)) from that on exposed surfaces of the dielectric layer 610 (e.g., silicon dioxide (SiO₂) or silicon nitride (Si₃N₄)). The nucleation may occur at a faster rate on the exposed surfaces of the first semiconductor regions 606 and the second semiconductor regions 608 (e.g., silicon (Si) or silicon germanium (SiGe)) than on the exposed surfaces of the dielectric layer 610 (e.g., silicon dioxide (SiO₂) or silicon nitride (Si₃N₄)), and thus an epitaxial layer of the third material may be formed on the exposed surfaces of the first semiconductor regions 606 and the second semiconductor regions 608 (e.g., silicon (Si) or silicon germanium (SiGe)), while an amorphous layer of the third material may be formed on the exposed surfaces of the dielectric layer 610 (e.g., silicon dioxide (SiO₂) or silicon nitride (Si₃N₄)), when the semiconductor structure 600 is exposed to a deposition gas in the first deposition process. In the subsequent first etch process, the amorphous layers of the third material formed on the exposed surfaces of the dielectric layer 610 can be etched at a faster rate than the epitaxial layers of the third material formed on the exposed surfaces of the first semiconductor regions 606 and the second semiconductor regions 608, by an appropriate etching gas. Thus, an overall result of the first deposition process and the first etch process combined can be epitaxial growth of the third material on the exposed surfaces of the first semiconductor regions 606 and the second semiconductor regions 608, while minimizing growth, if any, of the third material on the exposed surfaces of the dielectric layer 610.

In some embodiments, the deposition gas includes a silicon-containing precursor, a germanium containing precursor, and a dopant source. The silicon-containing precursor may include silane (SiH₄), disilane (Si₂H₆), tetrasilane (Si₄H₁₀), or a combination thereof. The germanium-containing precursor may include germane (GeH₄), germanium tetrachloride (GeCl₄), and digermane (Ge₂H₆). The dopant source may include, for example, boron, or gallium, depending upon the desired conductive characteristic of the second contact layer 618. The dopant source may include a precursor diborane (B₂H₆). The etching gas includes an etchant gas and a carrier gas. The etchant gas may include halogen-containing gas, such as hydrogen chloride (HCl), chlorine (Cl₂), or hydrogen fluoride (HF). The carrier gas may include nitrogen (N₂), argon (Ar), helium (He), or hydrogen (H₂).

The first deposition process and the first etch process may be performed at a low temperature less than about 450° C. and at a pressure of between 5 Torr and 600 Torr.

A cycle of the first deposition and first etch processes may be repeated as needed to obtain a desired thickness of the first contact layer 616 and the second contact layer 618. A thickness of the first contact layer 616 and the second contact layer 618 may be between about 30 Å and about 100 Å.

In block 530, a patterning process is performed to form a patterning stack 620 over the second semiconductor regions 608 so as to cover the second contact layer 618, as shown in FIG. 6C. The patterning process may be performed using a conventional photolithography patterning process.

The patterning stack 620 may be deposited onto exposed surfaces of the semiconductor structure 600 using a planarizing fill process (e.g., spin-coating) and subsequently patterned by a suitable lithography and etch process. The patterning stack 620 may be formed of organic dielectric layer (ODL), silicon anti-reflective coating (SiARC), or photoresist.

In block 540, a selective removal process (SRP) is performed to remove the first contact layer 616 (e.g., silicon germanium (SiGe)) selectively to the first semiconductor regions 606 (e.g., silicon (Si)) and the dielectric layer 610 (e.g., silicon dioxide (SiO₂) or silicon nitride (Si₃N₄)), as shown in FIG. 6D. The SRP may be performed in a processing chamber, such as the processing chamber 124 shown in FIG. 1, or the processing chamber 400 shown in FIG. 4.

The SRP includes a plasma etch using plasma effluents formed from a fluorine-containing precursor (e.g. nitrogen trifluoride (NF₃)). Plasma effluents from a remote plasma source (e.g., the remote plasma source 224 shown in FIG. 4) are flowed into a substrate processing region (e.g., the substrate processing region 428 shown in FIG. 4). The plasmas effluents react with exposed surfaces of the semiconductor structure 600 and selectively remove the first contact layer 616 (e.g., silicon germanium (SiGe)) while very slowly removing the first semiconductor regions 606 (e.g., silicon (Si)). Generally speaking, the SRP described herein is useful for removing Si_{(1-X)}Ge_{X} (including germanium i.e., X=1) faster than Si_{(1-Y)}Ge_{Y}, for all X>Y. In some embodiments, the etch selectivity of silicon germanium results partly from the presence of an ion suppressor (e.g., the perforated partition 422 shown in FIG. 4) positioned between a chamber plasma region (e.g., the chamber plasma region 426 shown in FIG. 4) and the substrate processing region (e.g., the substrate processing region 428 shown in FIG. 4).

The fluorine-containing precursor includes nitrogen trifluoride, fluorocarbon, atomic fluorine, diatomic fluorine, interhalogen fluoride (e.g. bromine trifluoride, chlorine trifluoride), sulfur hexafluoride, xenon difluoride, or a combination thereof. A diluent gas (e.g., argon (Ar), helium (He), nitrogen (N₂), or a combination thereof) is also flowed into the chamber plasma region where it is simultaneously excited in a plasma along with the fluorine-containing precursor. The diluent gas reduces diffusivity of plasma effluents and thus increases the etch selectivity of silicon germanium.

In some embodiments, the fluorine-containing precursor (e.g. nitrogen trifluoride (NF₃)) is supplied at a flow rate of between about 5 sccm (standard cubic centimeters per minute) and about 40 sccm, argon (Ar) at a flow rate of between about 4 sccm and about 1500 sccm, helium (He) at a flow rate of between about 100 sccm and about 5000 sccm, and nitrogen (N₂) at a flow rate of between about 100 sccm and about 5000 sccm. The SRP may be performed at a temperature of between about −20° C. and about 60° C. and at a pressure of between 1° Torr and 50° Torr. The etch selectivity of silicon germanium (SiGe) with a ratio of germanium (Ge) of 30% may be higher than 200:1 to phosphorus-doped silicon (Si:P), higher than 500:1 to thermal oxide (SiOₓ), and higher than 500:1 to silicon nitride (Si₃N₄).

In block 550, a conventional plasma ashing process is performed to remove the patterning stack 620, as shown in FIG. 6E. The plasma ashing process may be performed in a processing chamber, such as the processing chamber 122 shown in FIG. 1, or the processing chamber 200 shown in FIG. 2.

The plasma ashing process can use a plasma formed from a gas including oxygen (O₂). The ashing process can use a wet clean process using a solution, such as a mixture of sulfuric acid (H₂SO₄) and hydrogen peroxide (H₂O₂), to remove residue of the patterning stack 620 on the semiconductor structure 600.

In block 560, a second deposition process is performed, as shown in FIG. 6F. The second deposition process may be each performed in a processing chamber, such as the processing chamber 126, 128, or 130 shown in FIG. 1, or the processing chamber 300 shown in FIG. 3.

In the second deposition process, a metal layer 622 is formed on the exposed surfaces of the first semiconductor regions 606 and the second contact layer 618. The metal layer 622 contacts the second contact layer 618 and provides an electrical connection between a contact plug to be formed within the second openings 614 and the second semiconductor regions 608, while maintaining an electrical connection therethrough. The metal layer 622 may be formed of a metal material, such as titanium (Ti), cobalt (Co), nickel (Ni), molybdenum (Mo), or tantalum (Ta), or silicide thereof.

In some embodiments, the metal source may include a precursor that includes titanium (Ti), tantalum (Ta), cobalt (Co), nickel (Ni), or molybdenum (Mo) or combination thereof. The second deposition process may be each performed at a temperature of between about 300° C. and about 800° C. and at a pressure of between 1° Torr and 50° Torr.

In the second deposition process, a barrier metal layer 624 can also be formed on the exposed inner surfaces of the first opening 612 and the second opening 614, and the exposed surfaces of the dielectric layer 610. The barrier metal layer 624 protects the metal layer 622 and allow nucleation and growth of contact plugs in the first opening 612 and the second opening 614, as discussed below. The barrier metal layer 624 may be formed of a barrier metal material that is titanium nitride (TiN), or tantalum nitride (TaN). In some embodiments, the metal layer 622 is a silicide layer that is formed from a portion of the barrier metal layer 624 by use of a spike-anneal process. In some other embodiments, the metal layer 622 is a silicide layer that is formed by a separate selective deposition process that is performed before forming the barrier metal layer 624.

The second deposition process performed in block 560 may include any appropriate deposition process, such as atomic layer deposition (ALD), chemical vapor deposition (CVD), physical vapor deposition (PVD), or the like, in a processing chamber, such as the processing chamber 126, 128, or 130 shown in FIG. 1, at a temperature of between about 100° C. and about 300° C.

In block 570, a metal fill process is performed to form a first contact plug 626 in the first opening 612 and a second contact plug 628 in the second opening 614, as shown in FIG. 6G. The first contact plug 626 and the second contact plug 628 may be formed of contact plug metal material, such as tungsten (W), cobalt (Co), ruthenium (Ru), or molybdenum (Mo). The first contact plug 626 and the second contact plug 628 may include a metal that has a desirable work function. The metal fill process in block 570 may include a chemical vapor deposition (CVD) process using a tungsten-containing precursor, such as WF₆, or a cobalt-containing precursor, in a processing chamber, such as the processing chamber 126, 128, or 130 shown in FIG. 1.

After the metal fill process, the semiconductor structure 600 may planarized, such as by use of a chemical mechanical planarization (CMP) process.

### Alternate Example

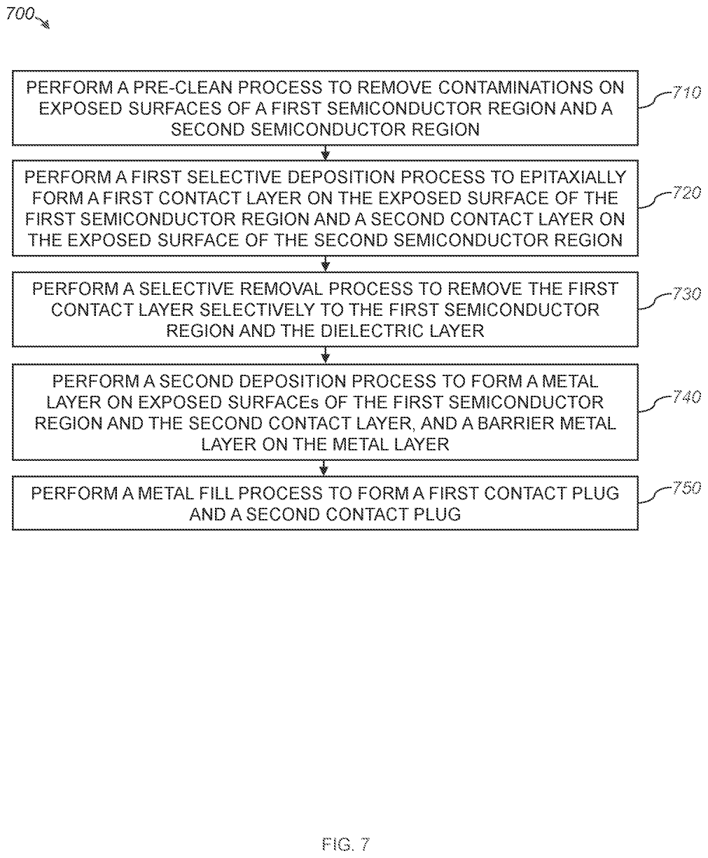

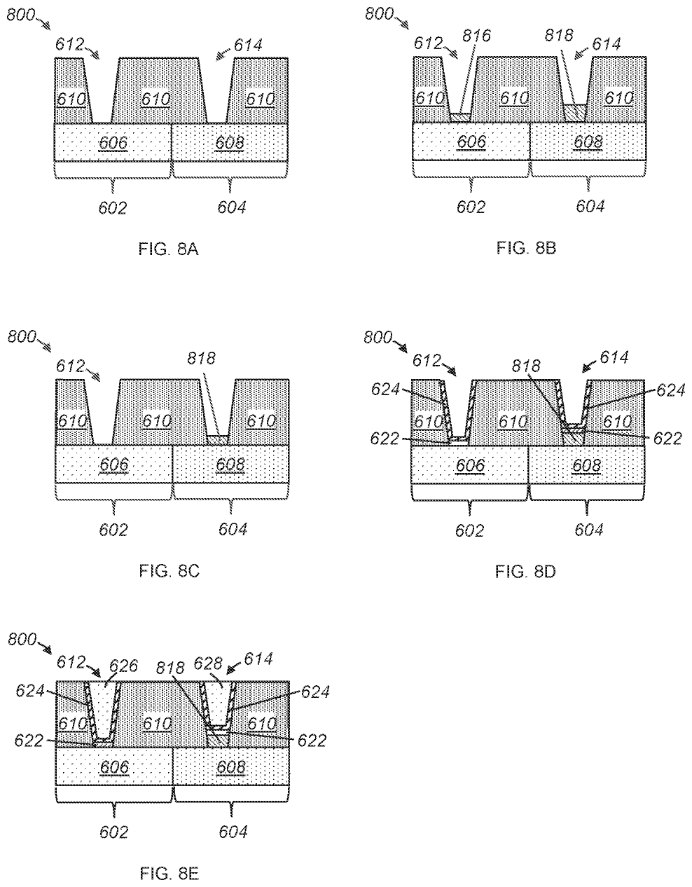

FIG. 7 depicts a process flow diagram of a method 700 of forming a contact layer in a semiconductor structure 800 according to a second embodiment of the present disclosure. FIGS. 8A, 8B, 8C, 8D, and 8E are cross-sectional views of a portion of the semiconductor structure 800 corresponding to various states of the method 700. It should be understood that FIGS. 8A, 8B, 8C, 8D, and 8E illustrate only partial schematic views of the semiconductor structure 800, and the semiconductor structure 800 may contain any number of transistor sections and additional materials having aspects as illustrated in the figures. It should also be noted that although the method illustrated in FIG. 7 is described sequentially, other process sequences that include one or more operations that have been omitted and/or added, and/or has been rearranged in another desirable order, fall within the scope of the embodiments of the disclosure provided herein. In the following description, the same reference numerals are used for the components that are substantially the same as those of the first embodiment, and the description of repeated components may be omitted.

The method 700 begins with a pre-clean process in block 710. The pre-clean process in block 710 is generally the same as the pre-clean process in block 510. The pre-clean process in block 710 may be tailored such that a growth rate of an epitaxial layer of the third material (e.g., silicon germanium (SiGe)) on exposed surfaces of the second semiconductor regions 608 (e.g., silicon germanium (SiGe)) is higher than a growth rate of an epitaxial layer of the third material (e.g., silicon germanium (SiGe)) on exposed surfaces of the first semiconductor regions 606 (e.g., silicon (Si)). Knobs for controlling the pre-clean process may include a gas chemistry, a gas ratio, a gas flow rate, a substrate temperature, temperature gradients, a chamber pressure, power and/or frequency of the power source, RF excitation frequencies, duty cycle and/frequency of RF powers, etch time, or a combination thereof. As discussed above, the modulation of the growth rate of a subsequently deposited epitaxial layer can be adjusted by controlling or adjusting the composition of the materials disposed at the surfaces of the first semiconductor regions 606 and the second semiconductor regions 608 and/or altering the crystal structure of the material at the surfaces of the first semiconductor regions 606 and the second semiconductor regions 608 after performing the pre-clean process.

In block 720, a first selective deposition process is performed to epitaxially form a first contact layer 816 on exposed surfaces of the first semiconductor regions 606 within the first opening 612, and a second contact layer 818 on exposed surfaces of the second semiconductor regions 608 within the second opening 614, as shown in FIG. 8B. The first selective deposition process in block 720 can in general be the same as the first selective deposition process in block 520. In some embodiments, due to the way the pre-clean process in block 710 was performed and thus the state of the surfaces of the first semiconductor regions 606 and the second semiconductor regions 608 during the first selective deposition process, the second contact layer 818 will grow to a greater thickness than the thickness of the first contact layer 816 during the same processing time period.

In some other embodiments of block 720, the process parameters used to simultaneously form the second contact layer 818 and the first contact layer 816 are adjusted and/or controlled such that the thickness of the second contact layer 818 formed on the second semiconductor regions 608 is greater than the thickness of the first contact layer 816 formed on the first semiconductor regions 606 during the same processing time period. It is believed that by controlling one or more of the deposition process parameters (e.g., temperature, process pressure, precursor gas composition, etc.) the growth rate of a silicon germanium (SiGe) containing second contact layer 818 on the silicon germanium (SiGe) containing second semiconductor regions 608 can be made significantly larger than the growth rate of the silicon germanium (SiGe) containing first contact layer 816 on the silicon containing first semiconductor regions 606.

In either of the block 720 examples, the first contact layer 816 can be formed to a thickness of between about 5 Å and about 100 Å and the second contact layer 818 can be formed to a thickness of between about 30 Å and about 100 Å, wherein the thickness of the first contact layer 816 is less than the thickness of the second contact layer 818.

In block 730, a selective removal process (SRP) is performed to remove the first contact layer 816 (e.g., silicon germanium (SiGe)) selectively to the first semiconductor regions 606 (e.g., silicon (Si)) and the dielectric layer 610 (e.g., silicon dioxide (SiO₂) or silicon nitride (Si₃N₄)), as shown in FIG. 8C. The SRP in block 730 is the same as the SRP in block 540. However, the second contact layer 818 is exposed (unlike the second contact layer 618 covered by the patterning stack 620 as shown in FIGS. 6C and 6D), and thus the second contact layer 818 is also selectively removed. In this process an amount of the first contact layer 816 and the second contact layer 818 is removed, such as all of the first contact layer 816, and thus leaving an amount of the second contact layer 818 remaining over the second semiconductor regions 608 due to the increased thickness of the second contact layer 818 versus the thickness of the first contact layer 816 formed during block 720. A cycle of the first selective deposition process in block 720 and the SRP in block 730 may be repeated as need to obtain a desired thickness of the second contact layer 818. A thickness of the second contact layer 618 may be between about 30 Å and about 100 Å.

In block 740, a second deposition process is performed to form the metal layer 622 and the barrier metal layer 624, as shown in FIG. 8D. The second deposition process provided in block 740 can be the same as the second deposition process in block 560.

In block 750, a metal fill process is performed to form the first contact plug 626 in the first opening 612 and the second contact plug 628 in the second opening 614, as shown in FIG. 6E. The metal fill process provided in block 750 can be the same as the metal fill process in block 670.

The embodiments described herein provide methods and system for forming a contact epitaxial layer within a trench on a selected portion of a transistor structure. The contact trench structure includes a metal contact plug formed within a trench between adjacent device modules, and contacts that interface between the contact plug and silicon-based channels in the device modules. The contacts are formed by a selective deposition process, reducing parasitic resistance. The metal contact plug is formed void-free by a deposition-each-deposition process, reducing contact resistance. The contact epitaxial layer may be p-type silicon germanium formed on an exposed surface of a p-type MOS device (e.g., silicon germanium) while no epitaxial layer may be formed on an n-type MOS (e.g., silicon) or a dielectric layer formed over the p-type MOS device and the n-type MOS device. The methods and systems do not require a patterning of an epitaxial layer using a photomask, and thus damages on a fabricated semiconductor structures are reduced.

While the foregoing is directed to embodiments of the present disclosure, other and further embodiments of the disclosure may be devised without departing from the basic scope thereof, and the scope thereof is determined by the claims that follow.

1. A method of forming an electrical contact in a semiconductor structure, comprising:
performing a pre-clean process on exposed surfaces of a plurality of first semiconductor regions and a plurality of second semiconductor regions formed on a substrate, wherein the exposed surfaces of the plurality of first and second semiconductor regions are each disposed within openings formed in a dielectric layer disposed over the substrate;
performing a first selective epitaxial deposition process to form a first contact layer on the exposed surfaces of the first semiconductor regions and a second contact layer on the exposed surface of the second semiconductor regions;
performing a patterning process to form a patterned stack, wherein the patterned stack comprises a patterned layer that comprises openings formed over the first contact layer disposed within each opening in the dielectric layer and a portion of the patterned layer that is disposed over each second contact layer disposed within each opening in the dielectric layer; and
performing a selective removal process to remove the first contact layer selectively to the plurality of first semiconductor regions, the dielectric layer, and the patterned layer.

2. The method of claim 1, wherein
the first semiconductor regions formed on the substrate comprises silicon,
the second semiconductor regions formed on the substrate comprises silicon germanium, and
the first contact layer and the second contact layer comprise silicon germanium.

3. The method of claim 1, wherein
the patterning stack comprises material selected from organic dielectric layer, silicon anti-reflective coating, and photoresist.

4. The method of claim 1, wherein the selective removal process is performed at:
a temperature of between −20° C. and 60° C.,
a pressure of between 1° Torr and 50° Torr,
a flow rate of a fluorine-containing precursor of between about 5 sccm and 40 sccm,
a flow rate of argon (Ar) of between 4 sccm and 1500 sccm,
a flow rate of helium (He) of between 100 sccm and 5000 sccm, and
a flow rate of nitrogen (N₂) of between 100 sccm and 5000 sccm.

5. The method of claim 1, further comprising:
subsequent to the selective removal process, performing an ashing process to remove the patterning stack.

6. The method of claim 5, further comprising:
subsequent to the ashing process, performing a second deposition process to form a metal layer on an exposed surface of the first semiconductor regions and an exposed surface of the second contact layer formed on the second semiconductor regions.

7. The method of claim 6, wherein
the metal layer comprises material selected from titanium (Ti) silicide, cobalt (Co) silicide, nickel (Ni) silicide, molybdenum (Mo) silicide, and tantalum (Ta) silicide.

8. A method of forming a contact layer in a semiconductor structure, the method comprising:
performing a pre-clean process on exposed surfaces of a plurality of first semiconductor regions and a plurality of second semiconductor regions formed on a substrate, wherein the exposed surfaces of the plurality of first and second semiconductor regions are each disposed within openings formed in a dielectric layer disposed over the substrate;
performing a first selective epitaxial deposition process to simultaneously form a first contact layer having a first thickness on the exposed surface of the first semiconductor regions and a second contact layer having a second thickness on the exposed surface of the second semiconductor regions, wherein the second thickness is larger than the first thickness; and
performing a selective removal process to remove the first contact layer and the second contact layer selectively to the plurality of first semiconductor regions, and the dielectric layer until the first contact layer is substantially removed from the first semiconductor regions and a portion of the second contact layer remains on the second semiconductor regions.

9. The method of claim 8, wherein
the first semiconductor regions formed on the substrate comprises silicon,
the second semiconductor regions formed on the substrate comprises silicon germanium, and
the first contact layer and the second contact layer comprise silicon germanium.

10. The method of claim 8, wherein the selective removal process is performed at:
a temperature of between −20° C. and 60° C.,
a pressure of between 1° Torr and 50° Torr,
a flow rate of a fluorine-containing precursor of between about 5 sccm and 40 sccm,
a flow rate of argon (Ar) of between 4 sccm and 1500 sccm,
a flow rate of helium (He) of between 100 sccm and 5000 sccm, and
a flow rate of nitrogen (N₂) of between 100 sccm and 5000 sccm.

11. The method of claim 8, further comprising:
performing a second selective epitaxial deposition process to form a metal layer on an exposed surface of the first semiconductor regions and an exposed surface of the second contact layer formed on the second semiconductor regions.

12. The method of claim 11, wherein
the metal layer comprises material selected from titanium (Ti) silicide, cobalt (Co) silicide, nickel (Ni) silicide, molybdenum (Mo) silicide, and tantalum (Ta) silicide.

13. A processing system, comprising:
a first processing chamber;
a second processing chamber;
a third processing chamber; and
a system controller configured to:
perform, in the first processing chamber, a pre-clean process on exposed surfaces of a plurality of first semiconductor regions and a plurality of second semiconductor regions formed on a substrate;
perform, in the second processing chamber, a first selective deposition process to epitaxially form a first contact layer on the exposed surfaces of the first semiconductor regions and a second contact layer on the exposed surface of the second semiconductor regions of the substrate; and
perform, in the third processing chamber, a selective removal process to remove the first contact layer selectively to the first semiconductor regions.

14. The processing system of claim 13, wherein the system controller is further configured to transfer the substrate among the first, second, and third processing chambers without breaking vacuum environment.

15. The processing system of claim 13, wherein
the first semiconductor regions formed on the substrate comprises silicon,
the second semiconductor regions formed on the substrate comprises silicon germanium, and
the first contact layer and the second contact layer comprise silicon germanium.

16. The processing system of claim 13, wherein the selective removal process in the third processing chamber is performed at:
a temperature of between −20° C. and 60° C.,
a pressure of between 1° Torr and 50° Torr,
a flow rate of a fluorine-containing precursor of between about 5 sccm and 40 sccm,
a flow rate of argon (Ar) of between 4 sccm and 1500 sccm,
a flow rate of helium (He) of between 100 sccm and 5000 sccm, and
a flow rate of nitrogen (N₂) of between 100 sccm and 5000 sccm.

17. The processing system of claim 13, further comprising:
a fourth processing chamber, wherein the system controller is further configured to:
perform, in the fourth processing chamber, a second deposition process to form a metal layer on an exposed surface of the first semiconductor regions and an exposed surface of the second contact layer formed on second semiconductor regions formed on the substrate, the metal layer comprising material selected from titanium (Ti) silicide, cobalt (Co) silicide, nickel (Ni) silicide, molybdenum (Mo) silicide, and tantalum (Ta) silicide.

18. The processing system of claim 17, further comprising:
a fifth processing chamber, wherein the system controller is further configured to:
perform, in the fifth processing chamber, a conformal deposition process to form a barrier metal layer on the metal layer, the barrier metal layer comprising material selected from titanium nitride (TiN) and tantalum nitride (TaN).

19. The processing system of claim 18, further comprising:
a sixth processing chamber,
wherein the system controller is further configured to perform, in the sixth processing chamber, prior to the second deposition process in the fourth processing chamber and subsequent to the selective removal process in the third processing chamber, performing an ashing process to remove a patterning stack.
